(19) United States
(12) Patent Application Publication
(10) Pub. No.: US 2010/0221907 A1
(43) Pub. Date: Sep. 2, 2010

(54) Method of Fabricating a Fuse for Use in a Semiconductor Device

(75) Inventors: Young Jin Choi, Suwon-si (KR); Jin Won Park, Seongnam-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/780,683

(22) Filed: May 14, 2010

Related U.S. Application Data
(62) Division of application No. 12/147,730, filed on Jun. 27, 2008.

(30) Foreign Application Priority Data
Oct. 31, 2007 (KR) 10-2007-0110721

(51) Int. Cl. H01L 21/44

(52) U.S. Cl. 438/601; 257/E21.476

(57) ABSTRACT

A fuse in a semiconductor device includes: first and second fuse patterns, each being in the shape of a bar, separated from each other in a blowing region; first and second contact plugs respectively coupled to the first and the second fuse patterns; and a third fuse pattern coupled to the first and the second fuse patterns through the first and the second contact plugs.

### CROSS-REFERENCE TO RELATED APPLICATION

This is a division of U.S. application Ser. No. 12/147,730 filed Jun. 27, 2008, which claims the priority benefit under USC 119 of KR 10-2007-0110721 filed Oct. 31, 2007, the entire respective disclosures of which are incorporated herein by reference.

### BACKGROUND OF THE INVENTION

The present invention generally relates to a fuse of a semiconductor device and a method for forming the same; and more specifically, to a technology of solving a problem generated by fuse blowing with a laser.

Generally, a semiconductor memory device representative of semiconductor devices can not perform a normal operation such as ‘read’ or ‘write’ operation if there is even one defective unit cell included in the semiconductor memory device. In this case, the semiconductor memory device is treated as a defective product. However, whenever the semiconductor memory device has a critical but petty defect, e.g., few defective unit cells, it is ineffective in a yield aspect to waste the semiconductor memory device as a defective product.

Conventionally, to increase a manufacturing yield, a defective unit cell in a normal cell array is replaced with a spare cell in a redundancy circuit also fabricated with the normal cell array in the semiconductor memory device and thus, it is prevented that the semiconductor memory device is treated as a defective product because of a partial and petty defect. As a result, the semiconductor memory device of which the partial and petty defect is repaired can be used as a normal product.

Similar to the normal cell array, the redundancy circuit includes a spare cell array having plural spare rows and plural spare columns. Through a repair operation, a row or a column having a defective unit cell in the normal cell array is replaced with a spare row or a spare column in the spare cell array.

After a plurality of unit cells for storing data and a plurality of circuits for reading/writing data are fabricated, a test for checking whether a plurality of unit cells are defective is performed. Then, even if there is a defective unit cell, an internal circuit is programmed so that an address of the replaced spare cell is assigned as an address corresponding to the defective memory cell. As a result, if the address corresponding to the defective unit cell is externally inputted to the semiconductor memory device, the replaced spare cell in the redundancy circuit instead of the defective unit cell is accessed.

One of the program methods of the internal circuit is to cut a fuse by a laser beam so as to store the address corresponding to a defective unit cell in an address decoder or a redundancy circuit. Herein, the fuse for transferring flow of electricity is designated to be selectively blown out when the laser beam is emitted. Further, plural fuses and their surrounding region including an insulating layer and a guarding structure are called a fuse box.

FIGS. 1a to 1c are diagrams illustrating a fuse 10 of a conventional semiconductor device.

Referring to FIG. 1a, the fuse 10 has a conductive layer to have a bar type. As not shown, a fuse box includes a plurality of fuses isolated from each other at a predetermined distance, for preventing damage when a neighboring fuse is blown out.

Referring to FIG. 1b, an insulating film 12 having a predetermined thickness is formed on the fuse 10. In a blowing process, a laser beam is emitted to cut the fuse 10 such as some of plural fuse in the fuse box, which selectively blown out because of corresponding to a defective unit cell.

Since the insulating film 12 has a property like a glass, laser energy is not absorbed in the insulating film 12 but passed through the insulating film 12. As a result, most of the laser energy is absorbed in the fuse 10, and the fuse 10 is thermally expanded by the laser energy. Finally, the fuse 10 is blown out and cut.

Referring to FIG. 1c, a stress due to the laser energy is concentrated in the fuse 10 so as to increase a pressure of thermal expansion and the thermal expansion causes a crack in the insulating film 12 over the fuse 10. If the fuse 10 is continuously stressed, an upper portion of the fuse 10 starts to be blown out, and later the fuse 10 are vaporized in the air.

FIGS. 2a and 2b are scanning electron micrographs (SEM) describing problems when a fuse in the conventional semiconductor device is blown out.

Referring to FIG. 2a, a blowing region of the fuse that absorbes laser energy in a blowing process is mostly vaporized or released in the air. However, if an upper portion of the fuse 10 is blown out before the fuse 10 absorbs laser energy sufficiently, the entire blowing region of the fuse is not vaporized. As a result, residues (A), e.g., remainder of conductive material, remain in the blowing region of the fuse, so that the fuse is not cut, i.e., cannot prohibit flow of electricity.

Meanwhile, referring to FIG. 2b, when the upper portion of the fuse 10 is blown out late although sufficient laser energy for blowing the fuse 10 out is supplied, a stress due to the laser energy is delivered to not only a lower portion of the fuse 10 but also a lower layer than the fuse 10. As a result, a crack (B) is generated in the lower layer than the fuse 10.

A thickness of the insulating film 12 formed on the fuse 10 is critical point of determining the generation of the residues (A) or the crack (B). However, it is very difficult to control the thickness of the insulating film 12 precisely to prevent the generation of residues or cracks. Thus, for controlling a thickness of an insulating film over a fuse, an additional and complicated process is required. Accordingly, productivity of the semiconductor device is decreased, and manufacturing coat is increased.

### BRIEF SUMMARY OF THE INVENTION

Various embodiments of the present invention are directed at separating a fuse pattern having a bar type from a blowing region to form first and second fuse patterns and providing a third fuse pattern connected through a contact plug connected to the first and second fuse patterns in the blowing region to increase a thickness margin of an insulating film disposed in an upper portion of the fuse, thereby facilitating a process.

According to an embodiment of the present invention, a fuse in a semiconductor device includes first and second fuse patterns being in the shape of a bar separated from each other in a blowing region, first and second contact plugs respectively coupled to the first and the second fuse patterns, and a third fuse pattern coupled to the first and the second fuse patterns through the first and the second contact plugs.

Preferably, the combination of the first to the third fuse patterns is bar-shaped in a plane view.

Preferably, both sides of the third fuse pattern in the blowing region overlaps one side of each of the first and the second fuse patterns in a plane view.

Preferably, the first and the second contact plugs are located in overlapped regions between the third fuse pattern and the first and the second fuse patterns.

Preferably, the first to the third fuse patterns include one selected from the group of an aluminum, a copper, and combinations thereof.

Preferably, the first and the second contact plugs include one selected from the group of an aluminum, a copper, and combinations thereof.

According to an embodiment of the present invention, a method of fabricating a fuse for use in a semiconductor memory device includes forming a third fuse pattern being bar-shaped in a blowing region, forming an insulation layer on the third fuse pattern, penetrating the insulation layer to form contact plugs coupled to both sides of the third fuse pattern, and forming first and second fuse patterns, each coupled to the contact plugs in the blowing region.

Preferably, the third fuse pattern is formed while a word line and a bit line are formed.

Preferably, the first to the third fuse patterns and the contact plugs include one selected from the group of an aluminum, a copper, and combinations thereof.

Preferably, the contact plugs are formed while an alternative one of a capacitor contact, a concave storage electrode, and a metal wire contact is formed.

Preferably, each of the first and the second fuse patterns is formed while an alternative one of a capacitor plate electrode and a metal wire is formed.

Preferably, the penetrating the insulation layer includes forming a contact pad between the contact plugs.

Preferably, the method of fabricating a fuse further includes defining a fuse box area on an insulation interlayer formed on the first and the second fuse patterns.

According to an embodiment of the present invention, a semiconductor device includes a fuse including a blowing region and non-blowing regions separated from each other and contact plugs for coupling the blowing region to the non-blowing regions, and an intervening layer located between the blowing region and the non-blowing regions of the fuse.

Preferably, the blowing region is located at lower level than the non-blowing regions.

Preferably, the fuse further includes contact pads for coupling the contact plugs located between the blowing region and the non-blowing regions of the fuse.

Preferably, the blowing region of the fuse and a word line are located at substantially same level.

Preferably, the non-blowing regions and an alternative one of a capacitor plate electrode and a metal wire are located at substantially same level.

Preferably, the contact plugs and an alternative one of a capacitor contact, a concave storage electrode, and a metal wire contact are located at substantially same level.

Preferably, the fuse is bar-shaped.

### BRIEF DESCRIPTION OF THE DRAWINGS

FIGS. 1a to 1c are diagrams illustrating a conventional fuse of a semiconductor device.

FIGS. 2a and 2b are SEM photographs illustrating problems generated in fuse blowing of a conventional semiconductor device.

FIGS. 3 and 4 are diagrams illustrating a fuse of a semiconductor device according to an embodiment of the present invention.

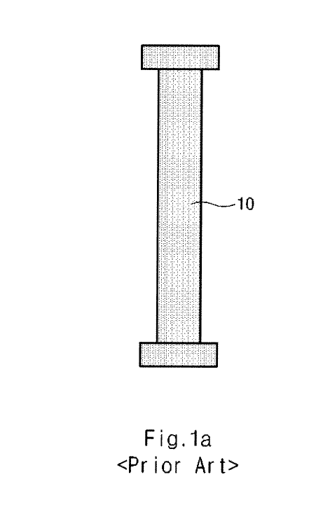

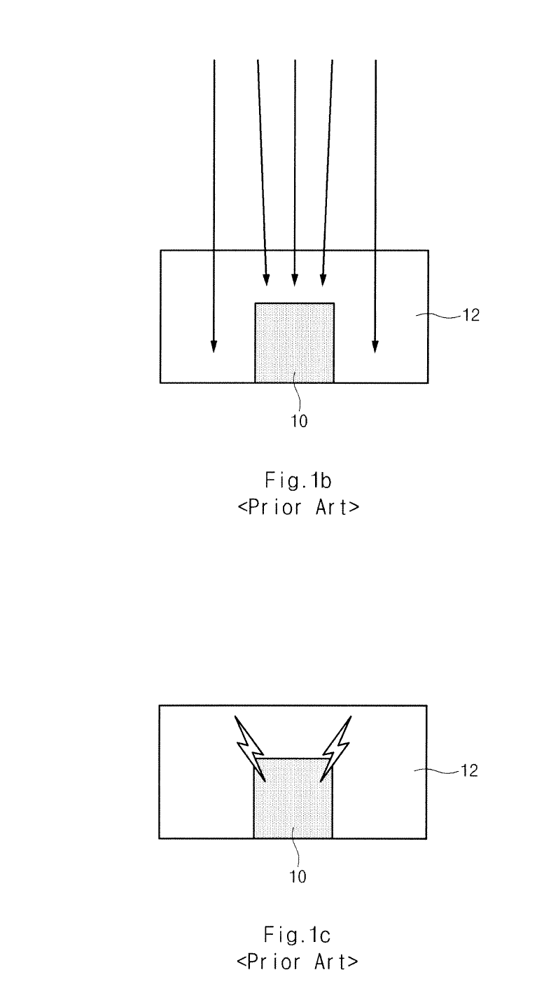

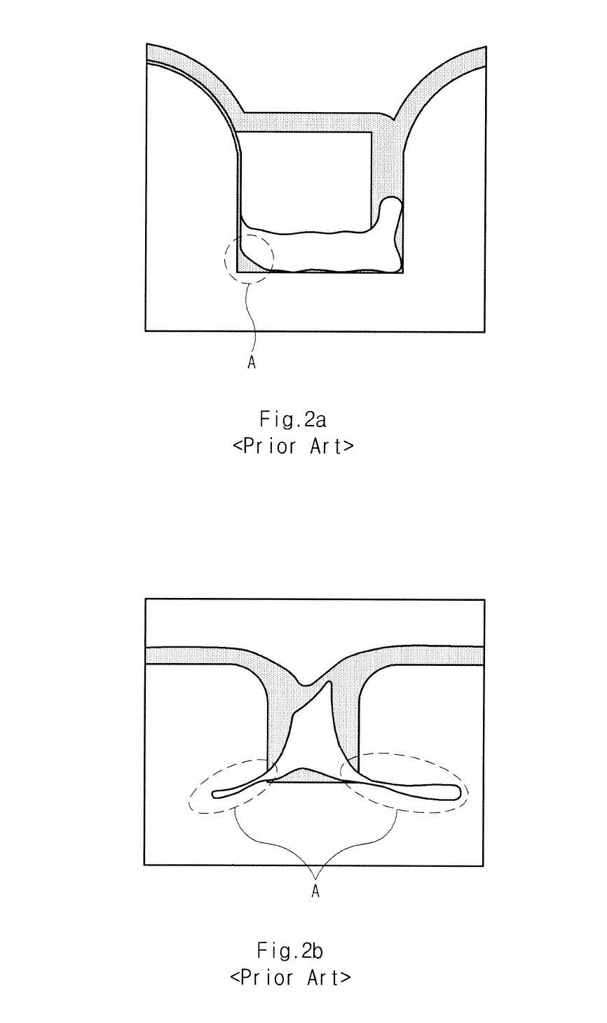

### DESCRIPTION OF EMBODIMENTS

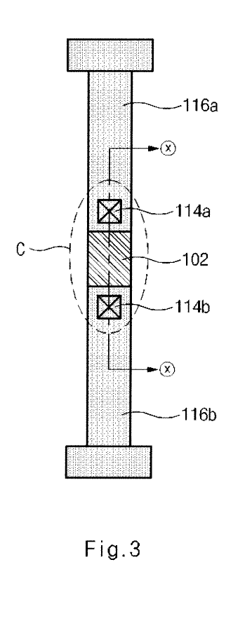

FIG. 3 is a plane diagram illustrating a fuse of a semiconductor device according to an embodiment of the present invention.

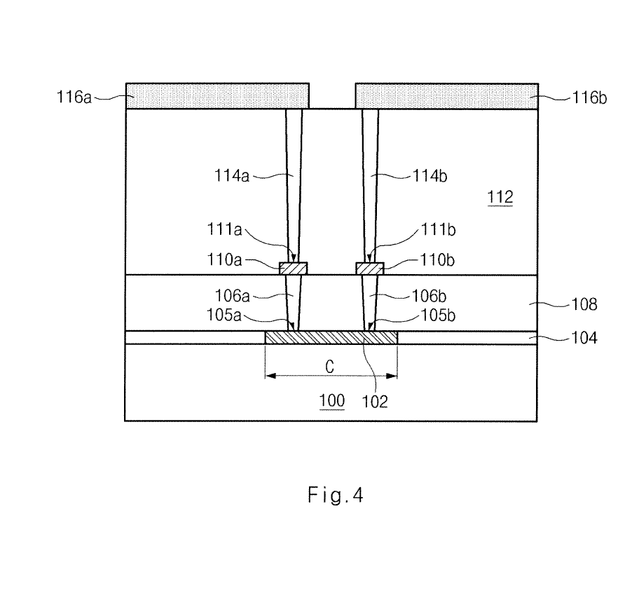

Referring to FIGS. 3 and 4, the fuse may include first and second fuse patterns 116a and 116b separated from each other with a given space, first and second contact plugs 114a and 114b formed over a semiconductor substrate 100 and connected respectively to the first and second fuse patterns 116a and 116b, and a third fuse pattern 102 for connecting the first and second fuse patterns 116a and 116b through the first and second contact plugs 114a and 114b.

The first and second fuse patterns 116a and 116b are formed to have a bar shape with a conductive material. A fuse blowing region (C) is disposed between the first and second fuse patterns 116a and 116b including the first and second contact plugs 114a and 114b.

The first and second contact plugs 114a and 114b are overlapped with the edges of the first and second fuse patterns 116a and 116b adjacent to the laser irradiation region (C).

FIG. 4 is a cross-sectional diagram illustrating a method for fabricating a semiconductor device, taken along x-x of FIG. 3.

Referring to FIG. 4, a conductive layer is formed over the semiconductor substrate 100. The conductive layer is etched by a photo-etching process with an exposure mask to form the third fuse pattern 102.

The exposure mask includes a shading pattern positioned at a portion overlapped with a fuse blowing part of a fuse blowing region. The third fuse pattern 102 is formed to have a bar type in the fuse blowing region. The third fuse pattern 102 includes a conductive layer having a metal layer selected from the group consisting of aluminum, copper and combinations thereof. The third fuse pattern 102 is formed in the fuse box region when a word line is formed.

A first insulating film 104 is formed over the resulting structure, and planarized to expose the third fuse pattern 102.

A second insulating film 108 is formed over the resulting structure.

The second insulating film 108 is etched by a photo-etching process with a contact mask to form lower contact holes 105a and 105b that exposes each edge part disposed at both sides of the third fuse pattern 102. The lower contact holes 105a and 105b are filled to form first and second contact plugs 106a and 106b. The lower contact holes 105a and 105b are formed in the fuse box region when a bit line contact hole is formed. The first and second contact plugs 106a and 106b are formed when a bit line contact plug is formed.

In the manufacturing of a semiconductor device, two elements each formed in a different region are formed to have the same height from the bottom of the semiconductor substrate. When a step difference is generated while a region of the semiconductor device is formed (that is, the elements each formed in a different region are different respectively in their heights), it is difficult to form a fine pattern due to the step difference.

A conductive layer for filling the lower contact holes 105a and 105b is formed over the resulting structure, and planarized for form the first and second contact plug 106a and 106b. The conductive layer includes a metal layer selected from the group consisting of aluminum, copper and combinations thereof.

Contact pads 110a and 110b connected respectively to the first and second contact plugs 106a and 106b are formed.

A third insulating film 112 is formed over the resulting structure. Upper contact holes 111a and 111b that exposes the contact pads 110a and 110b are formed by a photo-etching process with a contact mask.

The contact pads 110a and 110b are formed in the fuse box region when a bit line is formed. The contact pads 110a and 110b include a conductive layer having a metal layer selected from the group consisting of aluminum, copper and combinations thereof. The upper contact holes 111a and 111b are formed in the fuse box region when a storage node contact for forming a capacitor, a storage node having a concave type or a metal line contact is formed.

The third and fourth contact plugs 114a and 114b connected to a contact pad through the upper contact holes 111a and 111b. A process margin is not large because the upper contact holes 111a and 111b are aligned with the lower contact holes 105a and 105b. The contact pads 110a and 110b each having a larger area than that of the lower contact holes 105a and 105b are formed over the first and second contact plugs 106a and 106b obtained by filling the lower contact holes 105a and 105b to increase the process margin and reduce a resistance generated from connection of the first and second contact plugs 106a and 106b and the third and fourth contact plugs 114a and 114b.

A conductive layer for filling the contact holes 111a and 111b is formed over the resulting structure, and planarized to obtain the contact plugs 1114a and 114b. The conductive layer includes a metal layer selected from the group consisting of aluminum, copper and combinations thereof. The planarizing process is performed by a chemical mechanical polishing process or etch-back process.

The conductive layer connected to the contact plugs 114a and 114b is formed over the resulting structure, and etched by a photo-etching process with an exposure mask to form the first and second fuse patterns 116a and 116b.

The first and second fuse patterns 116a and 116b are formed to have a straight bar type with the third fuse pattern 102 as shown in FIG. 3. Both ends of the third fuse pattern 102 connected to the edge of the first and second fuse patterns 116a and 116b through the contact plugs 106a, 106b, 114a, 114b and the contact pads 110a, 110b, respectively.

The first and second fuse patterns 116a and 116b include a conductive layer having a metal layer selected from the group consisting of aluminum, copper and combinations thereof.

The first and second fuse patterns 116a and 116b are formed when a plate electrode of a capacitor or a metal line is formed.

In another embodiment of the present invention, the third fuse pattern 102 is formed when a bit line is formed without forming the contact pads 110a and 110b.

As described above, in a fuse of a semiconductor device and a method for forming the same according to an embodiment of the present invention, a fuse blowing region is partially separated and connected at a lower height than a fuse through a contact plug to increase a process margin when an insulating film located at a upper side of the fuse is formed in a fuse blowing process, thereby simplifying a process and improving yield and productivity of the semiconductor device.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method of fabricating a fuse for use in a semiconductor memory device, the method comprising:
forming a third fuse pattern being bar-shaped in a blowing region;
forming an insulation layer on the third fuse pattern;
penetrating the insulation layer to form contact plugs coupled to sides of the third fuse pattern; and
forming first and second fuse patterns, each coupled to the contact plugs in the blowing region.

2. The method according to claim 1, wherein the third fuse pattern is formed while a word line and a bit line are formed.

3. The method according to claim 1, wherein the first to the third fuse patterns and the contact plugs include a material selected from the group consisting of aluminum, copper, and combinations thereof.

4. The method according to claim 1, wherein the contact plugs are formed while an alternative one of a capacitor contact, a concave storage electrode, and a metal wire contact is formed.

5. The method according to claim 1, wherein the first and the second fuse patterns is formed while an alternative one of a capacitor plate electrode and a metal wire is formed.

6. The method according to claim 1, wherein the penetrating the insulation layer includes forming a contact pad between the contact plugs.

7. The method according to claim 1, further comprising defining a fuse box area on an insulation interlayer formed on the first and the second fuse patterns.
